(19) United States
(12) Patent Application Publication
(10) Pub. No.: US 2011/0148436 A1
(43) Pub. Date: Jun. 23, 2011

(54) SYSTEM AND METHOD FOR DETERMINING A NUMBER OF OBJECTS IN A CAPACITIVE SENSING REGION USING SIGNAL GROUPING

(75) Inventor: Tracy Scott Dattalo, Santa Clara, CA (US)

(73) Assignee: SYNAPTICS INCORPORATED, Santa Clara, CA (US)

(21) Appl. No.: 12/642,461

(22) Filed: Dec. 18, 2009

(51) Int. Cl. G01R 27/26

(52) U.S. Cl. 324/663

(57) ABSTRACT

An input device and method are provided that facilitate improved usability. The input device comprises an array of capacitive sensing electrodes and a processing system. The processing system is configured to receive sensing signals from the capacitive sensing electrodes and generate a plurality of sensing values, each of the plurality of sensing values corresponding to a sensing electrode in the first array of capacitive sensing electrodes. The processing system is further configured to produce a plurality of positional values corresponding to a plurality of groups of electrodes in the first array of capacitive sensing electrodes; analyze the plurality of positional values to determine if one or more clusters exist in the plurality of positional values; and determine a number of objects in the sensing region from the determined one or more clusters in the plurality of positional values.

### FIELD OF THE INVENTION

This invention generally relates to electronic devices, and more specifically relates to sensor devices and using sensor devices for producing user interface inputs.

### BACKGROUND OF THE INVENTION

Proximity sensor devices (also commonly called touch sensor devices) are widely used in a variety of electronic systems. A proximity sensor device typically includes a sensing region, often demarked by a surface, in which input objects may be detected. Example input objects include fingers, styli, and the like. The proximity sensor device may utilize one or more sensors based on capacitive, resistive, inductive, optical, acoustic and/or other technology. Further, the proximity sensor device may determine the presence, location and/or motion of a single input object in the sensing region, or of multiple input objects simultaneously in the sensor region.

The proximity sensor device may be used to enable control of an associated electronic system. For example, proximity sensor devices are often used as input devices for larger computing systems, including: notebook computers and desktop computers. Proximity sensor devices are also often used in smaller systems, including: handheld systems such as personal digital assistants (PDAs), remote controls, and communication systems such as wireless telephones and text messaging systems. Increasingly, proximity sensor devices are used in media systems, such as CD, DVD, MP3, video or other media recorders or players. The proximity sensor device may be integral or peripheral to the computing system with which it interacts.

In the past, some proximity sensor devices have had limited ability to detect and distinguish between one or more objects in the sensing region. For example, some capacitive sensor devices may detect a change in capacitance resulting from an object or objects being in the sensing region but may not be able to reliably determine if the change was caused by one object or multiple objects in the sensing region. This limits the flexibility of the proximity sensor device in providing different types of user interface actions in response to different numbers of objects or gestures with different numbers of objects.

This limitation is prevalent in some capacitive sensors generally referred to as “profile sensors”. Profile sensors use arrangements of capacitive electrodes to generate signals in response one or more objects in the sensing region. Taken together, these signals comprise a profile that may be analyzed determine the presence and location of objects in the sensing region. In a typical multi-dimensional sensor, capacitance profiles are generated and analyzed for each of multiple coordinate directions. For example, an “X profile” may be generated from capacitive electrodes arranged along the X direction, and a “Y profile” may be generated for electrodes arranged in the Y direction. These two profiles are then analyzed to determine the position of any object in the sensing region.

Because of ambiguity in the capacitive response, it may be difficult for the proximity sensor to reliably determine if the capacitive profile is the result of one or more objects in the sensing region. This may limit the ability of the proximity sensor to distinguish between one or more objects and thus to provide different interface actions in response to different numbers of objects.

Thus, what is needed are improved techniques for quickly and reliably distinguishing between one or more objects in a sensing region of a proximity sensor device, and in particular, object(s) in the sensing region of capacitive profile sensors. Other desirable features and characteristics will become apparent from the subsequent detailed description and the appended claims, taken in conjunction with the accompanying drawings and the foregoing technical field and background.

### BRIEF SUMMARY OF THE INVENTION

The embodiments of the present invention provide a device and method that facilitates improved sensor device usability. Specifically, the device and method provide improved device usability by facilitating the reliable determination of the number objects in a sensing region of a capacitive sensors. For example, the device and method may determine if one object or multiple objects are in the sensing region. The determination of the number of objects in the sensing region may be used to facilitate different user interface actions in response to different numbers of objects, and thus may improve sensor device usability.

In one embodiment, a sensor device comprises an array of capacitive sensing electrodes and a processing system coupled to the electrodes. The capacitive sensing electrodes are configured to generate sensing signals that are indicative of objects in a sensing region. The processing system is configured to receive sensing signals from the capacitive sensing electrodes and generate a plurality of sensing values, each of the plurality of sensing values corresponding to a sensing electrode in the first array of capacitive sensing electrodes. The processing system is further configured to produce a plurality of positional values corresponding to a plurality of groups of electrodes in the first array of capacitive sensing electrodes; analyze the plurality of positional values to determine if one or more clusters exist in the plurality of positional values; and determine a number of objects in the sensing region from the determined one or more clusters in the plurality of positional values. Thus, the sensor device facilitates the determination of the number of objects in the sensing region, and may be used to facilitate different user interface actions in response to different numbers of objects.

In another embodiment, a method is provided for determining a number of objects in a sensing region of a capacitive sensor with a first array of capacitive sensing electrodes. In this embodiment, the method comprises the steps of receiving sensing signals from the first array of capacitive sensing electrodes, generating a plurality of sensing values, each of the plurality of sensing values corresponding to a sensing electrode in the first array of capacitive sensing electrodes, producing a plurality of positional values corresponding to a plurality of groups of electrodes in the array of sensing electrodes, analyzing the plurality of positional values to determine if one or more clusters exist in the plurality of positional values; and determining a number of objects in the sensing region from the determined one or more clusters in the plurality of positional values. Thus, the method facilitates the determination of the number of objects in the sensing region, and may thus be used to facilitate different user interface actions in response to different numbers of objects.

### BRIEF DESCRIPTION OF DRAWINGS

The preferred exemplary embodiment of the present invention will hereinafter be described in conjunction with the appended drawings, where like designations denote like elements, and wherein:

FIG. 1 is a block diagram of an exemplary system that includes an input device in accordance with an embodiment of the invention;

FIG. 2 is a schematic view of an exemplary electrode array in accordance with an embodiment of the invention;

FIG. 3 is a top view an input device with one object in the sensing region in accordance with an embodiment of the invention;

FIG. 4 is a side view an input device with one object in the sensing region in accordance with an embodiment of the invention;

FIGS. 5 and 6 are graphs of sensing value magnitudes for one object in the sensing region in accordance with an embodiment of the invention;

FIG. 7 is a top view an input device with multiple objects in the sensing region in accordance with an embodiment of the invention;

FIG. 8 is a side view an input device with multiple objects in the sensing region in accordance with an embodiment of the invention;

FIGS. 9 and 10 are graphs of sensing value magnitudes for multiple objects in the sensing region in accordance with an embodiment of the invention;

FIG. 11 is a method for determining a number of objects in a sensing region in accordance with an embodiment of the invention;

FIGS. 12 and 13 are graphs of sensing values grouped into a plurality of groups in accordance with an embodiment of the invention;

FIGS. 14 and 15 are graphs of sensing values grouped into a plurality of groups in accordance with an embodiment of the invention;

FIGS. 16 and 17 are graphs of sensing values grouped into a plurality of groups and corresponding positional values in accordance with an embodiment of the invention; and

FIGS. 18 and 19 are graphs of sensing values grouped into a plurality of groups and corresponding clusters of positional values in accordance with an embodiment of the invention.

### DETAILED DESCRIPTION OF THE INVENTION

The following detailed description is merely exemplary in nature and is not intended to limit the invention or the application and uses of the invention. Furthermore, there is no intention to be bound by any expressed or implied theory presented in the preceding technical field, background, brief summary or the following detailed description.

The embodiments of the present invention provide a device and method that facilitates improved sensor device usability. Specifically, the device and method provide improved device usability by facilitating the reliable determination of the number objects in a sensing region of a capacitive sensors. For example, the device and method may determine if one object or multiple objects are in the sensing region. The determination of the number of objects in the sensing region may be used to facilitate different user interface actions in response to different numbers of objects, and thus may improve sensor device usability.

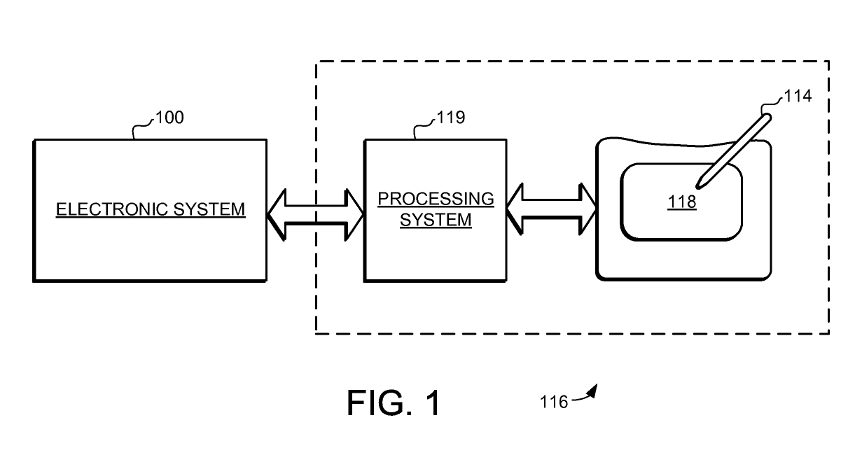

Turning now to the drawing figures, FIG. 1 is a block diagram of an exemplary electronic system 100 that operates with an input device 116. As will be discussed in greater detail below, the input device 116 may be implemented to function as an interface for the electronic system 100. The input device 116 has a sensing region 118 and is implemented with a processing system 119. Not shown in FIG. 1 is an array of sensing electrodes that are adapted to capacitively sense objects in the sensing region 118.

The input device 116 is adapted to provide user interface functionality by facilitating data entry responsive to sensed objects. Specifically, the processing system 119 is configured to determine positional information for multiple objects sensed by a sensor in the sensing region 118. This positional information may then be used by the system 100 to provide a wide range of user interface functionality.

The input device 116 is sensitive to input by one or more input objects (e.g. fingers, styli, etc.), such as the position of an input object 114 within the sensing region 118. “Sensing region” as used herein is intended to broadly encompass any space above, around, in and/or near the input device in which sensor(s) of the input device is able to detect user input. In a conventional embodiment, the sensing region of an input device extends from a surface of the sensor of the input device in one or more directions into space until signal-to-noise ratios prevent sufficiently accurate object detection. The distance to which this sensing region extends in a particular direction may be on the order of less than a millimeter, millimeters, centimeters, or more, and may vary significantly with the type of sensing technology used and the accuracy desired. Thus, embodiments may require contact with the surface, either with or without applied pressure, while others do not. Accordingly, the sizes, shapes, and locations of particular sensing regions may vary widely from embodiment to embodiment.

Sensing regions with rectangular two-dimensional projected shape are common, and many other shapes are possible. For example, depending on the design of the sensor array and surrounding circuitry, shielding from any input objects, and the like, sensing regions may be made to have two-dimensional projections of other shapes. Similar approaches may be used to define the three-dimensional shape of the sensing region. For example, any combination of sensor design, shielding, signal manipulation, and the like may effectively define a sensing region 118 that extends some distance into or out of the page in FIG. 1.

In operation, the input device 116 suitably detects one or more input objects (e.g. the input object 114) within the sensing region 118. The input device 116 thus includes a sensor (not shown) that utilizes any combination sensor components and sensing technologies to implement one or more sensing regions (e.g. sensing region 118) and detect user input such as presences of object(s). Input devices may include any number of structures, including one or more capacitive sensor electrodes, one or more other electrodes, or other structures adapted to detect object presence. Devices that use capacitive electrodes for sensing are advantageous to ones requiring moving mechanical structures (e.g. mechanical switches) as they may have a substantially longer usable life.

For example, sensor(s) of the input device 116 may use arrays or other patterns of capacitive sensor electrodes to support any number of sensing regions 118. Examples of the types of technologies that may be used to implement the various embodiments of the invention may be found in U.S. Pat. Nos. 5,543,591, 5,648,642, 5,815,091, 5,841,078, and 6,249,234.

In some capacitive implementations of input devices, a voltage is applied to create an electric field across a sensing surface. These capacitive input devices detect the position of an object by detecting changes in capacitance caused by the changes in the electric field due to the object. The sensor may detect changes in voltage, current, or the like.

As another example, some capacitive implementations utilize transcapacitive sensing methods based on the capacitive coupling between sensor electrodes. Transcapacitive sensing methods are sometimes also referred to as “mutual capacitance sensing methods.” In one embodiment, a transcapacitive sensing method operates by detecting the electric field coupling one or more transmitting electrodes with one or more receiving electrodes. Proximate objects may cause changes in the electric field, and produce detectable changes in the transcapacitive coupling. Sensor electrodes may transmit as well as receive, either simultaneously or in a time multiplexed manner. Sensor electrodes that transmit are sometimes referred to as the “transmitting sensor electrodes,” “driving sensor electrodes,” “transmitters,” or “drivers”—at least for the duration when they are transmitting. Other names may also be used, including contractions or combinations of the earlier names (e.g. “driving electrodes” and “driver electrodes.” Sensor electrodes that receive are sometimes referred to as “receiving sensor electrodes,” “receiver electrodes,” or “receivers”—at least for the duration when they are receiving. Similarly, other names may also be used, including contractions or combinations of the earlier names. In one embodiment, a transmitting sensor electrode is modulated relative to a system ground to facilitate transmission. In another embodiment, a receiving sensor electrode is not modulated relative to system ground to facilitate receipt.

In FIG. 1, the processing system (or “processor”) 119 is coupled to the input device 116 and the electronic system 100. Processing systems such as the processing system 119 may perform a variety of processes on the signals received from the sensor(s) and force sensors of the input device 116. For example, processing systems may select or couple individual sensor electrodes, detect presence/proximity, calculate position or motion information, or interpret object motion as gestures.

The processing system 119 may provide electrical or electronic indicia based on positional information and force information of input objects (e.g. input object 114) to the electronic system 100. In some embodiments, input devices use associated processing systems to provide electronic indicia of positional information and force information to electronic systems, and the electronic systems process the indicia to act on inputs from users. One example system response is moving a cursor or other object on a display, and the indicia may be processed for any other purpose. In such embodiments, a processing system may report positional and force information to the electronic system constantly, when a threshold is reached, in response criterion such as an identified stroke of object motion, or based on any number and variety of criteria. In some other embodiments, processing systems may directly process the indicia to accept inputs from the user, and cause changes on displays or some other actions without interacting with any external processors.

In this specification, the term “processing system” is defined to include one or more processing elements that are adapted to perform the recited operations. Thus, a processing system (e.g. the processing system 119) may comprise all or part of one or more integrated circuits, firmware code, and/or software code that receive electrical signals from the sensor and communicate with its associated electronic system (e.g. the electronic system 100). In some embodiments, all processing elements that comprise a processing system are located together, in or near an associated input device. In other embodiments, the elements of a processing system may be physically separated, with some elements close to an associated input device, and some elements elsewhere (such as near other circuitry for the electronic system). In this latter embodiment, minimal processing may be performed by the processing system elements near the input device, and the majority of the processing may be performed by the elements elsewhere, or vice versa.

Furthermore, a processing system (e.g. the processing system 119) may be physically separate from the part of the electronic system (e.g. the electronic system 100) that it communicates with, or the processing system may be implemented integrally with that part of the electronic system. For example, a processing system may reside at least partially on one or more integrated circuits designed to perform other functions for the electronic system aside from implementing the input device.

In some embodiments, the input device is implemented with other input functionality in addition to any sensing regions. For example, the input device 116 of FIG. 1 is implemented with buttons or other input devices near the sensing region 118. The buttons may be used to facilitate selection of items using the proximity sensor device, to provide redundant functionality to the sensing region, or to provide some other functionality or non-functional aesthetic effect. Buttons form just one example of how additional input functionality may be added to the input device 116. In other implementations, input devices such as the input device 116 may include alternate or additional input devices, such as physical or virtual switches, or additional sensing regions. Conversely, in various embodiments, the input device may be implemented with only sensing region input functionality.

Likewise, any positional information determined a processing system may be any suitable indicia of object presence. For example, processing systems may be implemented to determine “one-dimensional” positional information as a scalar (e.g. position or motion along a sensing region). Processing systems may also be implemented to determine multi-dimensional positional information as a combination of values (e.g. two-dimensional horizontal/vertical axes, three-dimensional horizontal/vertical/depth axes, angular/radial axes, or any other combination of axes that span multiple dimensions), and the like. Processing systems may also be implemented to determine information about time or history.

Furthermore, the term “positional information” as used herein is intended to broadly encompass absolute and relative position-type information, and also other types of spatial-domain information such as velocity, acceleration, and the like, including measurement of motion in one or more directions. Various forms of positional information may also include time history components, as in the case of gesture recognition and the like. As will be described in greater detail below, positional information from the processing systems may be used to facilitate a full range of interface inputs, including use of the proximity sensor device as a pointing device for selection, cursor control, scrolling, and other functions.

In some embodiments, an input device such as the input device 116 is adapted as part of a touch screen interface. Specifically, a display screen is overlapped by at least a portion of a sensing region of the input device, such as the sensing region 118. Together, the input device and the display screen provide a touch screen for interfacing with an associated electronic system. The display screen may be any type of electronic display capable of displaying a visual interface to a user, and may include any type of LED (including organic LED (OLED)), CRT, LCD, plasma, EL or other display technology. When so implemented, the input devices may be used to activate functions on the electronic systems. In some embodiments, touch screen implementations allow users to select functions by placing one or more objects in the sensing region proximate an icon or other user interface element indicative of the functions. The input devices may be used to facilitate other user interface interactions, such as scrolling, panning, menu navigation, cursor control, parameter adjustments, and the like. The input devices and display screens of touch screen implementations may share physical elements extensively. For example, some display and sensing technologies may utilize some of the same electrical components for displaying and sensing.

It should be understood that while many embodiments of the invention are to be described herein the context of a fully functioning apparatus, the mechanisms of the present invention are capable of being distributed as a program product in a variety of forms. For example, the mechanisms of the present invention may be implemented and distributed as a sensor program on computer-readable media. Additionally, the embodiments of the present invention apply equally regardless of the particular type of computer-readable medium used to carry out the distribution. Examples of computer-readable media include various discs, memory sticks, memory cards, memory modules, and the like. Computer-readable media may be based on flash, optical, magnetic, holographic, or any other storage technology.

As noted above, the input device 116 is adapted to provide user interface functionality by facilitating data entry responsive to sensed proximate objects and the force applied by such objects. Specifically, the input device 116 provides improved device usability by facilitating the reliable determination of the number objects in the sensing region 118. For example, the input device 116 may determine if one object or multiple objects are in the sensing region 118. The determination of the number of objects in the sensing region 118 may be used in determining positional information for the one or multiple objects, and further may be used to provide different user interface actions in response to different numbers of objects, and thus may improve sensor device usability.

In a typical embodiment, the input device 116 comprises an array of capacitive sensing electrodes and a processing system 119 coupled to the electrodes. The capacitive sensing electrodes are configured to generate sensing signals that are indicative of objects in the sensing region 118. The processing system 119 receives sensing signals from the capacitive sensing electrodes and generates a plurality of sensing values, each of the plurality of sensing values corresponding to a sensing electrode in the array of capacitive sensing electrodes.

From those sensing values, the processing system 119 can determine positional information for objects in the sensing region. And in accordance with the embodiments of the invention, the processing system 119 is configured to determine if one or more objects is in the sensing region 118, and may thus distinguish between situations where one object is in the sensing region 118 and situations where two objects are in the sensing region 118. To facilitate this determination, the sensing region 118 is configured to produce a plurality of positional values from the sensing signals received from the electrodes. These positional values correspond to a plurality of groups of electrodes in the first array of capacitive sensing electrodes. The processing system 119 is configured to analyze the plurality of positional values to determine if one or more clusters exist in the plurality of positional values, and determine a number of objects in the sensing region from the determined one or more clusters in the plurality of positional values. Thus, the processing system 119 facilitates the determination of the number of objects in the sensing region 118, and may thus be used to facilitate different user interface actions in response to different numbers of objects.

As noted above, the input device 116 may be implemented with a variety of different types and arrangements of capacitive sensing electrodes. To name several examples, the capacitive sensing device may be implemented with electrode arrays that are formed on multiple substrate layers, typically with the electrodes for sensing in one direction (e.g., the “X” direction) formed on a first layer, while the electrodes for sensing in a second direction (e.g., the “Y” direction are formed on a second layer. In other embodiments, the electrodes for both the X and Y sensing may be formed on the same layer. In yet other embodiments, the electrodes may be arranged for sensing in only one direction, e.g., in either the X or the Y direction. In still another embodiment, the electrodes may be arranged to provide positional information in polar coordinates, such as “r” and “θ” as one example. In these embodiments the electrodes themselves are commonly arranged in a circle or other looped shape to provide “θ”, with the shapes of individual electrodes used to provide “r”.

Also, a variety of different electrode shapes may be used, including electrodes shaped as thin lines, rectangles, diamonds, wedge, etc. Finally, a variety of conductive materials and fabrication techniques may be used to form the electrodes. As one example, the electrodes are formed by the deposition and etching of conductive ink on a substrate.

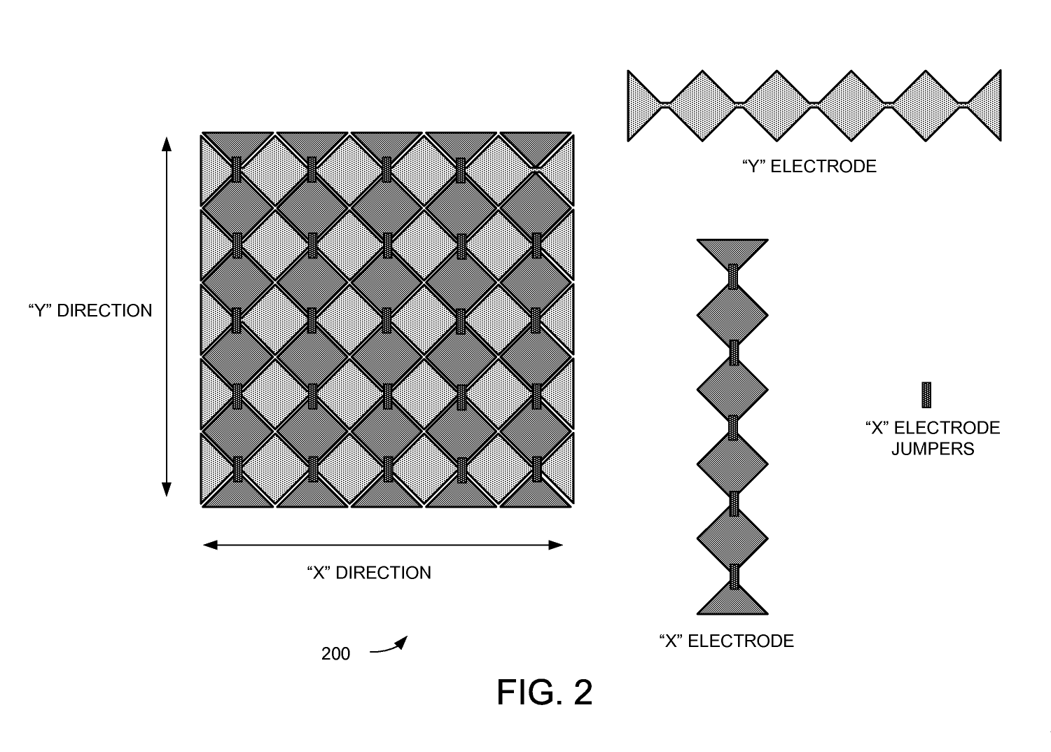

Turning now to FIG. 2, one example of capacitive array of sensing electrodes 200 is illustrated. These are examples of sensing electrodes that are typically arranged to be “under” or on the opposite side of the surface that is to be “touched” by a user of the sensing device. In this example, the electrodes are configured to sense object position and/or motion in the X direction are formed on the same layer with electrodes configured to sense object position and/or motion in the Y direction. These electrodes are formed with “diamond” shapes that are connected together in a string to form individual X and Y electrodes. It should be noted that while the diamonds of the X and Y electrodes are formed on the same substrate layer, a typical implementation will use “jumpers” formed above, on a second layer, to connect one string of diamonds together. So coupled together, each string of jumper connected diamonds comprises one X or one Y electrode.

In the example of FIG. 2, electrode jumpers for X electrodes are illustrated. Specifically, these jumpers connect one vertical string of the diamonds to form one X electrode. The corresponding connections between diamonds in the Y electrode are formed on the same layer and with the diamonds themselves. Such a connection is illustrated in the upper corner of electrodes 200, where one jumper is omitted to show the connection of the underlying Y diamonds.

Again, it should be emphasized that the sensing electrodes 200 are just one example of the type of electrodes that may be used to implement the embodiments of the invention. For example, some embodiments would include more or less numbers of electrodes. In other examples, the electrodes may be formed on multiple layers. In yet other examples, the electrodes may implemented with an array of electrodes that have multiple rows and columns of discrete electrodes.

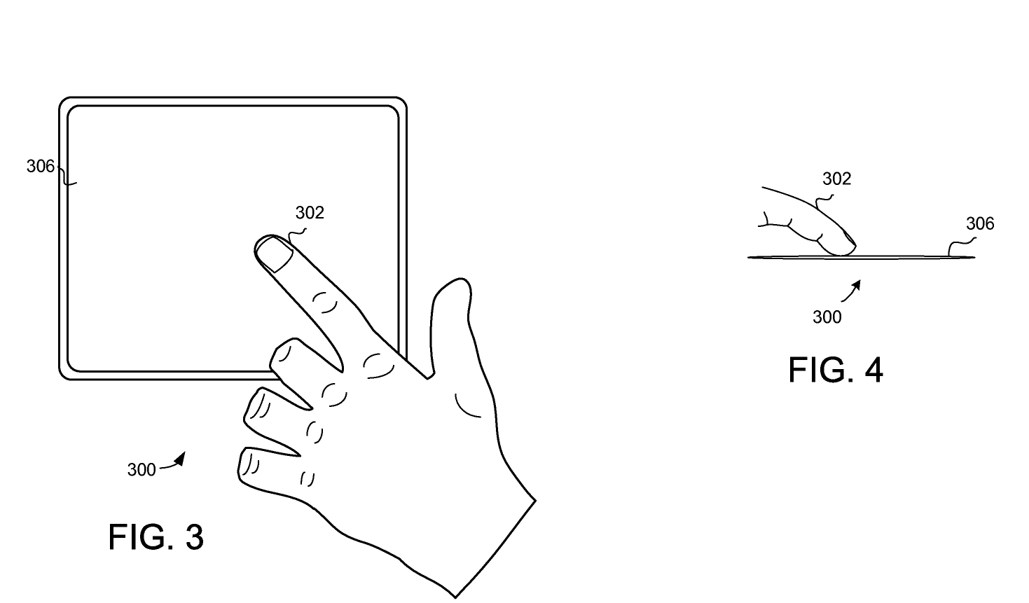

Turning now to FIGS. 3 and 4, examples of an object in a sensing region are illustrated. Specifically, FIGS. 3 and 4 show top and side views of an exemplary input device 300. In the illustrated example, user's finger 302 provides input to the device 300. Specifically, the input device 300 is configured to determine the position of the finger 302 within the sensing region 306 using a sensor. For example, the input device 300 may be configured using a plurality of electrodes configured to capacitively detect objects such as the finger 306, and a processor configured to determine the position of the fingers from the capacitive detection.

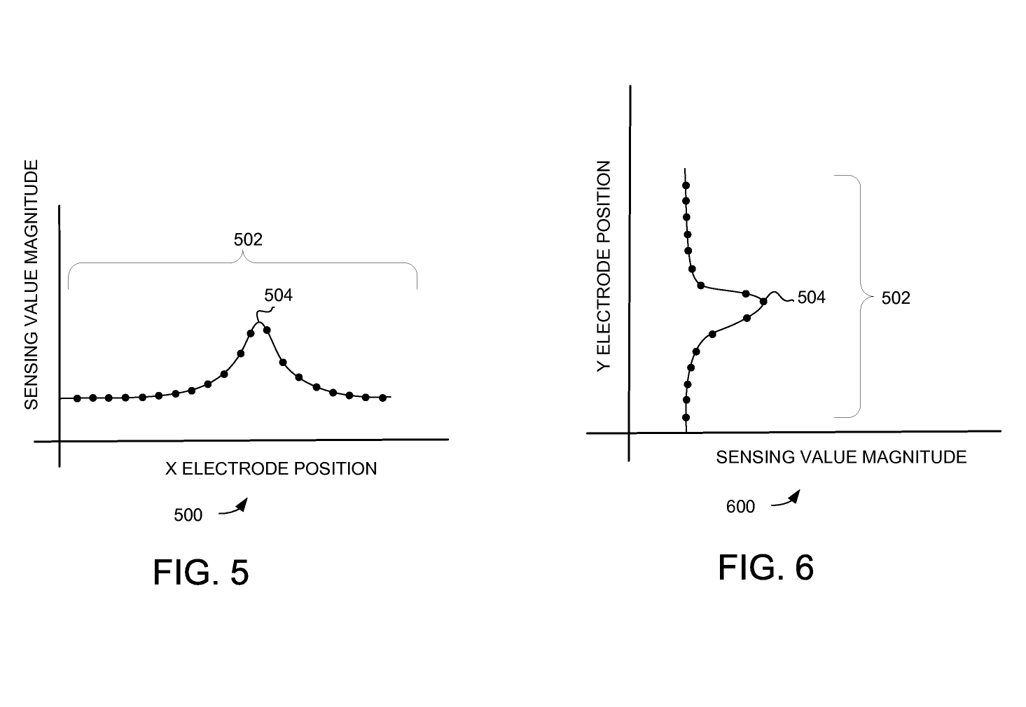

Turning now to FIGS. 5 and 6, graphs 500 and 600 illustrate exemplary sensing values 502 generated from X and Y electrodes in response to the user's finger 302 being in the sensing region 306. In these figures, each sensing value 502 is represented as a dot, and with the magnitude of the sensing value plotted against the position of the corresponding X electrode (FIG. 5) or Y electrode (FIG. 6). As illustrated in FIGS. 5 and 6, the magnitude of the sensing values are indicative of the location of the finger 302, and thus may be used to determine the X and Y coordinates of the finger 302 position. Specifically, when analyzed, the sensing values 502 define a curve, the extrema 504 of which may be determined as used to determine the position of an object (e.g., finger 302) in the sensing region.

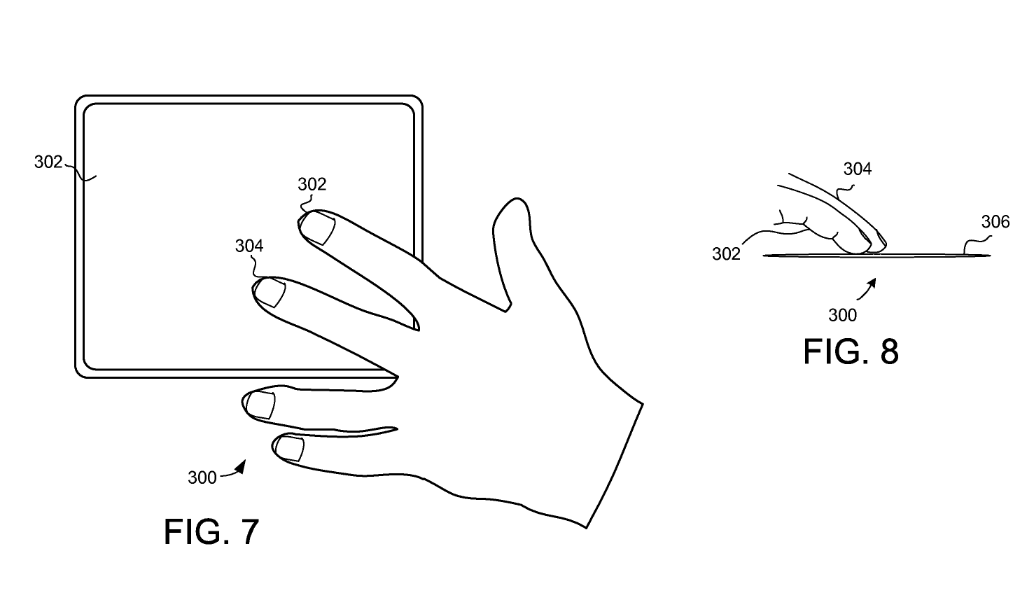

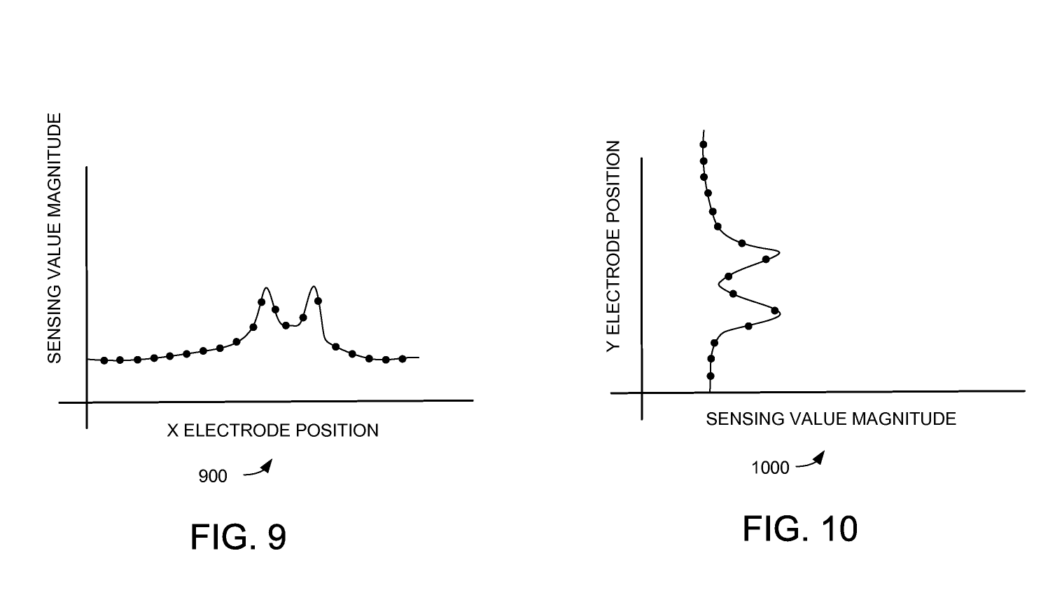

Turning now to FIGS. 7 and 8, second examples of objects in a sensing region are illustrated. Again, FIGS. 7 and 8 show top and side views of an exemplary input device 300. In the illustrated example, user's fingers 302 and 304 provide input to the device 300. Turning now to FIGS. 9 and 10, graphs 900 and 1000 illustrate exemplary sensing values generated from X and Y electrodes in response to the user's fingers 302 and 304 being in the sensing region 306. As illustrated in FIGS. 9 and 10, the magnitude of the sensing values are indicative of the location of the fingers 302 and 304, and thus may be used to determine the X and Y coordinates of the position of fingers 302 and 304.

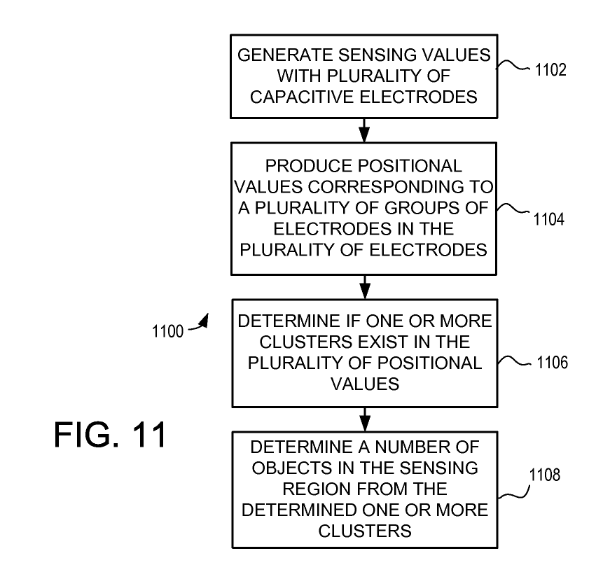

Turning now to FIG. 11, a method 1100 for determining the number of objects in a sensing region is illustrated. In general, the method 1100 receives sensing signals from an array of capacitive sensing electrodes, generates a plurality of positional values, and analyzes the plurality of positional values to determine if one or more clusters exist in the plurality of positional values. From those clusters the number of objects in the sensing region may be determined. Thus, the method 1100 facilitates the determination of the number of objects in the sensing region, and may thus be used to facilitate different user interface actions in response to different numbers of objects.

The first step 1102 is to generate sensing values with a plurality of capacitive electrodes. As noted above, a variety of different technologies may be used in implementing the input device, and these various implementations may generate signals indicative of object presence in a variety of formats. As one example, the input device may generate signals that correlate to the magnitude of a measured capacitance associated with each electrode. These signals may be based upon measures of absolute capacitance, transcapacitance, or some combination thereof. Furthermore, these signals may then be sampled, amplified, filtered, or otherwise conditioned as desirable to generate sensing values corresponding to the electrodes in the input device.

The next step 1104 is to produce positional values corresponding to a plurality of groups of electrodes. In this step, sensing values corresponding to subsets of electrodes, referred to herein as groups of electrodes, are used to generate the positional values. The groups of electrodes used for generating positional values may be selected and defined in a variety of ways. As one specific example, each group of electrodes may comprise a specified number of electrodes. Furthermore, each group of electrodes may comprise non-overlapping electrodes (where each electrode is only in one group) or overlapping electrodes (where some electrodes are members of multiple groups). In one specific embodiment, each group of electrodes comprises three electrodes, with the groups overlapping such that each electrode is a member of multiple groups of electrodes.

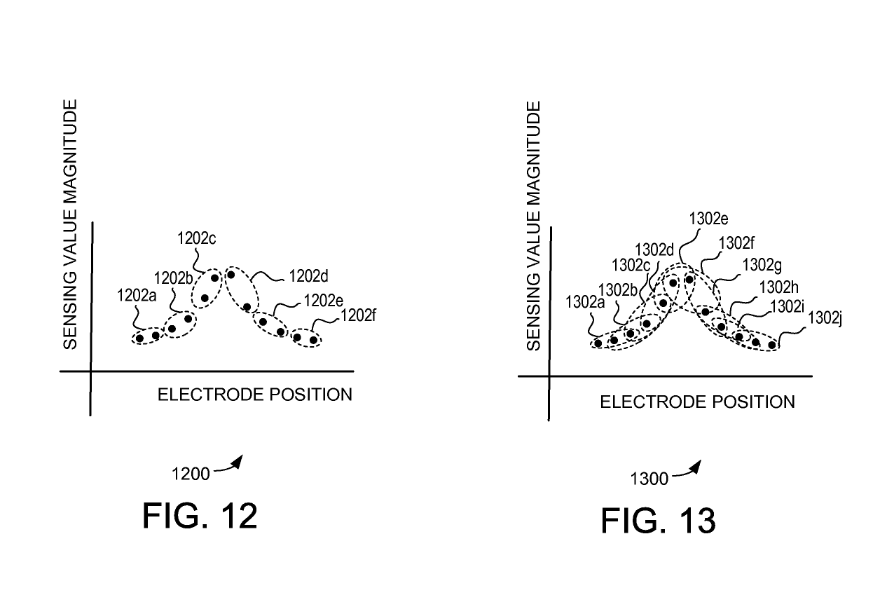

Turning briefly to FIG. 12, a graph 1200 illustrates an exemplary plurality of sensing values that are grouped into a plurality of groups of sensing values 1202a-f. Again, each of the sensing values corresponds to a capacitive measurement associated with an electrode in the input device, and thus each group of sensing values corresponds to a group of electrodes. In this example, each of the groups of sensing values 1202a-f is non-overlapping, and specifically each group includes two sensing values. Thus, none of the sensing values 1202a-f is a member of more than one group. Thus, in this example, each of the groups of sensing values 1202a-f would be used to generate a positional value, and thus 6 positional values would be generated from the 12 sensing values.

Turning briefly to FIG. 13, a graph 1300 illustrates a second exemplary plurality of sensing values that are grouped into a second plurality of groups of sensing values 1302a-j. Again, each of the sensing values corresponds to capacitive measurement associated with an electrode in the input device, and thus each group of sensing values corresponds to a group of electrodes. In this example, each of the groups of sensing values 1302a-j includes three sensing values. Furthermore, in this example each group of sensing values overlaps with at least one other group. Stated another way, most (but not all) sensing values in this example are members of more than one group. In this example, each of the groups of sensing values 1302a-j would be used to generate a positional value, and thus 10 positional values would be generated from the 12 sensing values.

Returning to FIG. 11, each of the groups of sensing values is used to generate a positional value. In general, the positional values are an estimation of the location of extrema in the sensing values generated from the group of sensing values corresponding to the group electrodes. A variety of different techniques may be used to estimate the extrema, and thus to generate the positional values. For example, various interpolation/extrapolation techniques maybe used.

As one specific example, where each group of sensing values includes three sensing values a, b, and c, where sensing value b corresponds to the ith electrode, sensing value a corresponds to the i−1 electrode, and sensing value c corresponds to the i+1 electrode, the positional value xᵢ corresponding to these sensing values may be determined by:

$${x}_{i} = i + {f}_{i} \\ where \\ {f}_{i} = \frac{p - q}{2 max ( p ; q )} \\ and where \\ p = b - a \\ q = b - c . \qquad Equation 1$$

In Equation 1, the positional value xᵢ indicates the position of the extrema in the sensing values as determined from the sensing values a, b, and c. Thus, fᵢ is a fractional offset for the location of the extrema as measured from the location i of the electrode corresponding to sensing value b. In general, Equation 1 subtracts sensing values from adjacent electrodes in each group of electrodes and divides the difference by twice the maximum of the subtracted sensing values. This serves as an interpolation of the sensing values and is thus an approximation of the extrema in the sensing values. Stated more specifically, Equation 1 provides an estimation of the location of the extrema generated from the group of sensing values a, b and c.

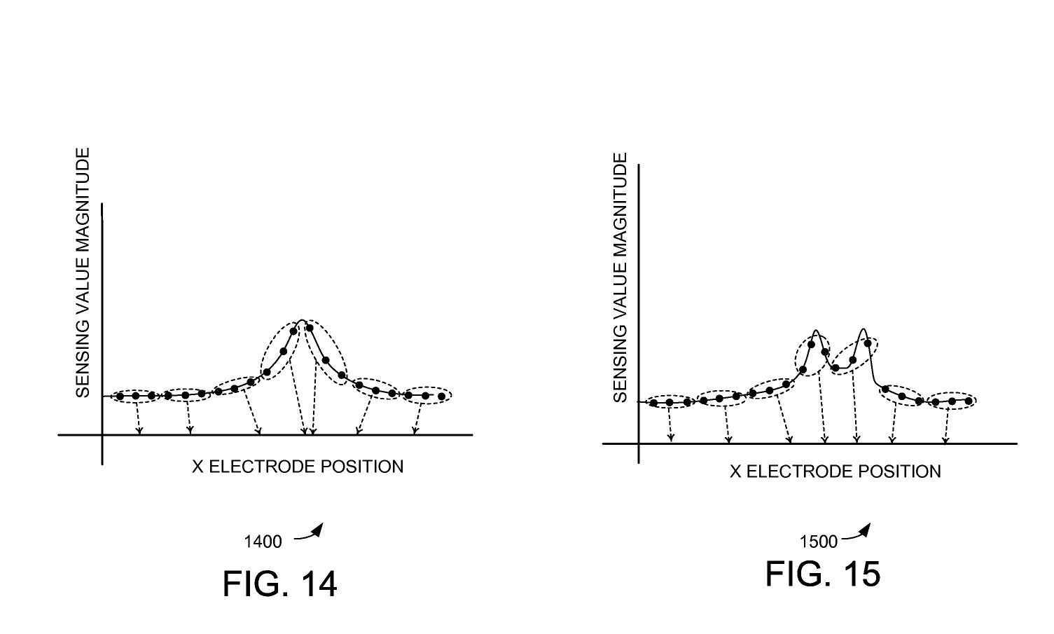

Turning now to FIGS. 14 and 15, examples of positional values corresponding to a plurality of groups of electrodes are illustrated for the sensing values illustrated in FIG. 5 and FIG. 9, respectively. Thus, FIG. 14 illustrates examples of positional values for one object in the sensing region, and FIG. 15 illustrates examples of positional values for two objects in the sensing region. In these figures the positional values corresponding to each group of electrodes is indicated by the line extending from the group to the location of the positional value. Again, the positional values are each an estimation of the location of the extrema based on the corresponding sensing values. Thus, FIGS. 14 and 15 illustrate positional values for each group of electrodes as relative positions along the axis. In these examples, each group includes three non-overlapping sensing values. As can be seen in these figures, 7 positional values are generated from each of 7 groups of sensing values.

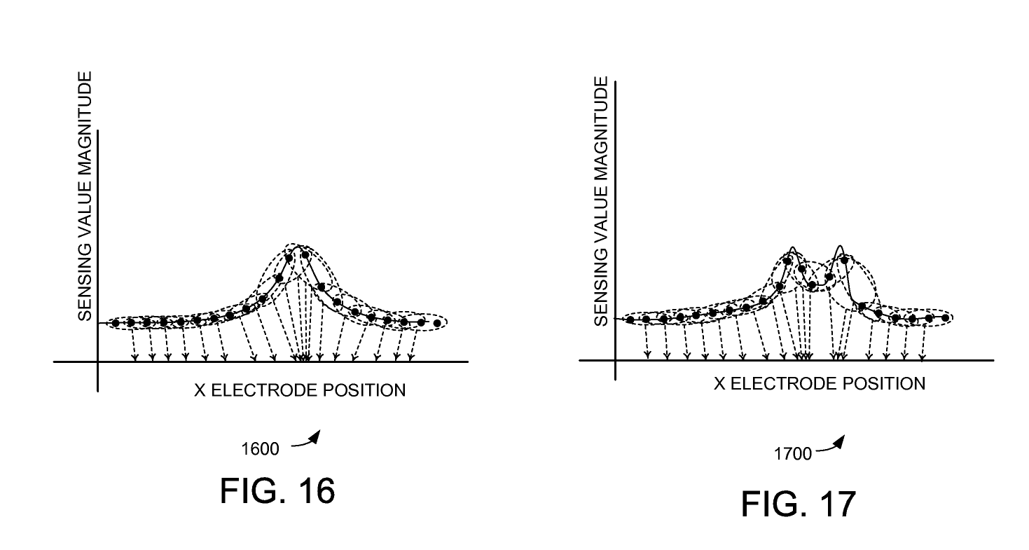

Turning now to FIGS. 16 and 17, second examples of positional values corresponding to a plurality of groups of electrodes are illustrated for the sensing values illustrated in FIG. 5 and FIG. 9 respectively. In these examples, each group includes three overlapping sensing values. Because the groups overlap, there are a greater number of groups, and thus a greater number of positional values are generated. Specifically, 19 positional values are generated from each of 19 overlapping groups of sensing values.

Returning to FIG. 11, the next step 1106 is to determine if one or more clusters exist in the positional values. A variety of different techniques may be used to determine the number of clusters in the positional values. For example, a weighted average of the location of each positional value may be used to determine the number of clusters. It should be understood that a variety of mathematic techniques could be used to determine if a localized cluster exists. It also should be noted that this step may involve the determination of the actual count of clusters in the positional values (e.g., 1, 2, 3, etc.), or it may more simply involve the determination that one or more clusters in the positional values exist.

The next step 1108 is to determine a number of objects in the sensing region from the determined one or more clusters. Again, this step may involve the determination of the actual count of objects in the sensing region (e.g., 1, 2, 3, etc.), or it may more simply involve the determination that one or more objects are in the sensing region.

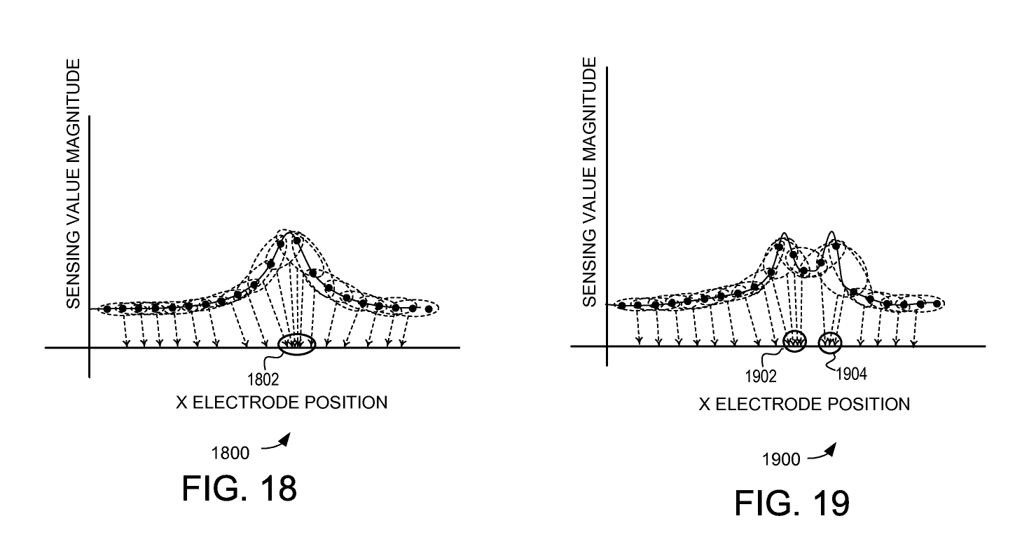

Turning now to FIGS. 18 and 19, clusters 1802, 1902 and 1904 are illustrated in the positional values. As can be seen in these examples, the existence of one cluster 1802 is indicative of one object in the sensing region (e.g., finger 302) while the existence of two clusters 1902 and 1904 are indicative of more than one object in the sensing region (e.g., fingers 302 and 304).

It should be noted that while the example of FIGS. 18 and 19 determines a number of objects in the sensing region from sensing values generated by the X electrodes, that the same determination may be made from sensing values generated by the Y electrodes. In this implementation, the Y array of sensing electrodes is grouped into a second plurality of groups, positional values are determined for each of the second plurality of groups, and one or more clusters are identified. This determination may serve as an independent indication of one or more objects in the sensing region or may be used to confirm or reject the indication made with the X electrodes.

Once the number of objects has been determined, it may be used for facilitating different user interface actions in response to different numbers of objects and thus can improve sensor device usability. For example, the determination that multiple fingers are in a sensing region may be used to initiate gestures such as enhanced scrolling, selecting, etc.

Thus, a sensor device is provided that comprises an array of capacitive sensing electrodes and a processing system coupled to the electrodes. The capacitive sensing electrodes are configured to generate sensing signals that are indicative of objects in a sensing region. The processing system is configured to receive sensing signals from the capacitive sensing electrodes and generate a plurality of sensing values, each of the plurality of sensing values corresponding to a sensing electrode in the first array of capacitive sensing electrodes. The processing system is further configured to produce a plurality of positional values corresponding to a plurality of groups of electrodes in the first array of capacitive sensing electrodes; analyze the plurality of positional values to determine if one or more clusters exist in the plurality of positional values; and determine a number of objects in the sensing region from the determined one or more clusters in the plurality of positional values. Thus, the sensor device facilitates the determination of the number of objects in the sensing region, and can thus be used to facilitate different user interface actions in response to different numbers of objects.

The embodiments and examples set forth herein were presented in order to best explain the present invention and its particular application and to thereby enable those skilled in the art to make and use the invention. However, those skilled in the art will recognize that the foregoing description and examples have been presented for the purposes of illustration and example only. The description as set forth is not intended to be exhaustive or to limit the invention to the precise form disclosed.

What is claimed is:

1. A sensor device comprising:
A first array of capacitive sensing electrodes, each of the first array of capacitive sensing electrodes configured to generate a sensing signal indicative of objects in a sensing region;
a processing system coupled to the first array of capacitive sensing electrodes, the processing system configured to:
receive sensing signals from the first array of capacitive sensing electrodes and generate a plurality of sensing values, each of the plurality of sensing values corresponding to a sensing electrode in the first array of capacitive sensing electrodes;
produce a plurality of positional values corresponding to a plurality of groups of electrodes in the first array of capacitive sensing electrodes;
analyze the plurality of positional values to determine if one or more clusters exist in the plurality of positional values; and
determine a number of objects in the sensing region from the determined one or more clusters in the plurality of positional values.

2. The sensor device of claim 1 wherein each of the plurality of groups of electrodes overlaps with at least one other of the groups of electrodes in the first array of capacitive sensing electrodes.

3. The sensor device of claim 1 wherein each of the plurality of groups of electrodes comprises at least three electrodes.

4. The sensor device of claim 1 wherein the processor is configured to produce the plurality of positional values corresponding to the plurality of groups of electrodes in the first array of sensing electrodes by:
interpolating sensing values from electrodes in each group of electrodes.

5. The sensor device of claim 1 wherein the processor is configured to produce the plurality of positional values corresponding to the plurality of groups of electrodes in the first array of sensing electrodes by:
subtracting sensing values from adjacent electrodes in each group of electrodes; and
dividing by a maximum of the subtracted sensing values.

6. The sensor device of claim 1 wherein the first array of capacitive sensing electrodes is arranged in a first direction, and further comprising:
a second array of capacitive sensing electrodes, each of the second array of capacitive sensing electrodes configured to generate a sensing signal indicative of objects in the sensing region, the second array of capacitive sensing electrodes arranged in a second direction different from the first direction; and
wherein the processing system is further coupled to the second array of capacitive sensing electrodes, and wherein the processing system is further configured to:
receive second sensing signals from the second array of capacitive sensing electrode and generate a second plurality of sensing values, each of the second plurality of sensing values corresponding to a sensing electrode in the second array of capacitive sensing electrodes;
produce a second plurality of positional values corresponding to a second plurality of groups of electrodes in the second array of capacitive sensing electrodes;
analyze the second plurality of positional values to determine if one or more clusters exist in the second plurality of positional values; and
determine the number of objects in the sensing region from the determined one or more clusters in the second plurality of positional values.

7. A sensor device comprising:
a first array of capacitive sensing electrodes arranged in a first direction, each of the first array of sensing electrodes configured to generate a sensing signal indicative of objects in a sensing region;
a second array of capacitive sensing electrodes arranged in a second direction different from the first direction, each of the second array of sensing electrodes configured to generate a sensing signal indicative of objects in the sensing region;
a processing system coupled to the first and second array of capacitive sensing electrodes, the processing system configured to:
receive sensing signals from the first and second arrays of capacitive sensing electrodes and generate a plurality of sensing values, each of the plurality of sensing values corresponding to a sensing electrode in the first and second arrays of capacitive sensing electrodes;
for each of a first plurality of groups of sensing electrodes in the first array of capacitive sensing electrodes, interpolate sensing values corresponding the group of sensing electrodes to produce a positional value, thereby producing a first plurality of positional values;
for each of a second plurality of groups of sensing electrodes in the second array of capacitive sensing electrodes, interpolate sensing values corresponding the group of sensing electrodes to produce a positional value, thereby producing a second plurality of positional values;
analyze the first plurality of positional values determine a first number of clusters existing in the first plurality of positional values;
analyze the second plurality of positional values determine a second number of clusters existing in the second plurality of positional values;
determine a number of objects in the sensing region from the first and second number of clusters.

8. A method of determining a number of objects in a sensing region of a capacitive sensor with a first array of capacitive sensing electrodes, the method comprising:
receiving sensing signals from the first array of capacitive sensing electrodes;
generating a plurality of sensing values, each of the plurality of sensing values corresponding to a sensing electrode in the first array of capacitive sensing electrodes;
producing a plurality of positional values corresponding to a plurality of groups of electrodes in the array of sensing electrodes;
analyzing the plurality of positional values to determine if one or more clusters exist in the plurality of positional values; and
determining a number of objects in the sensing region from the determined one or more clusters in the plurality of positional values.

9. The method of claim 8 wherein each of the plurality of groups of electrodes overlaps with at least one other of the groups of electrodes in the first array of sensing electrodes.

10. The method of claim 8 wherein each of the plurality of groups of electrodes comprises at least three electrodes.

11. The method of claim 8 wherein the step of producing a plurality of positional values corresponding to a plurality of groups of electrodes in the first array of sensing electrodes comprises:
interpolating sensing values from electrodes in each group of electrodes.

12. The method of claim 8 wherein the step of producing a plurality of positional values corresponding to a plurality of groups of electrodes in the first array of sensing electrodes comprises:
subtracting sensing values from adjacent electrodes in each group of electrodes; and
dividing by a maximum of the subtracted sensing values.

13. The method of claim 8 wherein the first array of sensing electrodes is arranged in a first direction and further comprising the steps of:
receiving sensing signals from a second array of sensing electrodes, the second array of sensing electrodes arranged in a second direction different from the first direction;
generating a second plurality of sensing values, each of the second plurality of sensing values corresponding to a sensing electrode in the second array sensing electrodes;
producing a second plurality of positional values corresponding to a second plurality of groups of electrodes in the second array of sensing electrodes;
analyzing the second plurality of positional values to determine if one or more clusters exist in the second plurality of positional values; and
determining the number of objects in the sensing region from the determined one or more clusters in the second plurality of positional values.

14. A program product, comprising:
A) a sensor program, the sensor program configured to:
receive sensing signals from an array of capacitive sensing electrodes and generate a plurality of sensing values, each of the plurality of sensing values corresponding to a sensing electrode in the array of capacitive sensing electrodes;
for each of a plurality of groups of sensing electrodes in the array of capacitive sensing electrodes, produce a positional value corresponding to the group of sensing electrodes, thereby producing a plurality of positional values;
analyze the plurality of positional values determine if one or more clusters exist in the plurality of positional values; and
determine a number of objects in the sensing region from the determined one or more clusters; and
B) computer-readable media bearing the proximity sensor program.

15. The program product of claim 14 wherein each of the plurality of groups of electrodes overlaps with at least one other of the groups of electrodes in the array of capacitive sensing electrodes.

16. The program product of claim 14 wherein each of the plurality of groups of electrodes comprises at least three electrodes.

17. The program product of claim 14 wherein the processor is configured to produce the plurality of positional values corresponding to the plurality of groups of electrodes in the array of sensing electrodes by:
interpolating sensing values from electrodes in each group of electrodes.

18. The program product of claim 14 wherein the processor is configured to produce the plurality of positional values corresponding to the plurality of groups of electrodes in the array of sensing electrodes by:
subtracting sensing values from adjacent electrodes in each group of electrodes;
dividing by a maximum of the subtracted sensing values.
